(19) United States
(12) Patent Application Publication
(10) Pub. No.: US 2026/0247566 A1
(43) Pub. Date: Aug. 20, 2026

(54) COLD PLATE FOR OPTICAL CAGE

(71) Applicant: Cisco Technology, Inc., San Jose, CA (US)

(72) Inventors: Yonggou Chen, Shanghai (CN); Vic Hong Chia, Sunnyvale, CA (US); Hua Yang, Tracy, CA (US); Kai Cao, Fremont, CA (US); Kuan-Chieh Chen, Granite Bay, CA (US)

(21) Appl. No.: 19/055,119

(22) Filed: Feb. 17, 2025

(51) Int. Cl. H05K 7/20

(52) U.S. Cl. CPC H05K 7/20254; H05K 7/20272

(57) ABSTRACT

In one embodiment, an apparatus includes an inlet configured to obtain a fluid, an outlet; a manifold, and at least a first port assembly. The manifold includes a first flow chamber and a second flow chamber. The first flow chamber obtains the fluid from the inlet, and the second flow chamber provides the fluid to the outlet. The first port assembly includes a lower first port assembly tunnel, an upper first port assembly tunnel, and a u-turn first port assembly tunnel, wherein the fluid is provided from the first flow chamber to the lower first port assembly tunnel, provided from the lower first port assembly tunnel to the u-turn first port assembly tunnel, and provided from the u-turn first port assembly tunnel to the upper first port assembly tunnel. The fluid is provided from the upper first port assembly tunnel to the second flow chamber.

### TECHNICAL FIELD

The present disclosure relates to cooling components in optical networks.

### BACKGROUND

Optical networking uses light signals to transmit data through fiberoptic cables. Equipment, e.g., optical components, used in optical networks facilitates the ability to communicate over long distances through the fiberoptic cables. Optical cages or optical cage systems are generally arranged to enable optical components such as mirrors and lenses to be rigidly mounted along an optical axis. When components contained in an optical cage become heated when the components are in use, the performance of the components may be compromised. That is, the performance of the components may not meet expectations. As a result, cooling systems are provided to cool optical cages. Cooling systems that include cold plates, while capable of cooling optical cages, generally have drawbacks including, but not limited to including, relatively long cooling flow paths, pressure drops, relatively complex structures, relatively large footprints, relatively high leakage risks, soft tube connections, and a propensity to cause heating of optical modules that are downstream from the cold plates.

### BRIEF DESCRIPTION OF THE DRAWINGS

The disclosure will be readily understood by the following detailed description in conjunction with the accompanying drawings in which:

FIG. 1 is a block diagram representation of a parallel flow cold plate in accordance with an embodiment.

FIG. 2 is a process flow diagram which illustrates a process of providing cooling using a parallel flow cold plate in accordance with an embodiment.

FIG. 3 is a diagrammatic representation of an overall fluid flow within a parallel flow cold plate in accordance with an embodiment.

FIG. 4A is a diagrammatic representation of a port assembly that is suitable for use in a parallel flow cold plate in accordance with an embodiment.

FIG. 4B is a diagrammatic representation of a parallel flow cold plate that includes a plurality of port assemblies, e.g., port assembly 410 of FIG. 4A, in accordance with an embodiment.

FIG. 5A is a diagrammatic representation of a flow of fluid through a parallel flow cold plate, e.g., parallel flow cold plate 400 of FIG. 4B, prior to the fluid being heated or warmed in accordance with an embodiment.

FIG. 5B is a diagrammatic representation of a flow of fluid through a parallel flow cold plate, e.g., parallel flow cold plate 400 of FIGS. 4B and 5A, after the fluid is heated or warmed in accordance with an embodiment.

FIG. 5C is a diagrammatic representation of a flow of fluid through u-turn tunnels of a parallel flow cold plate, e.g., u-turn tunnels 412b of parallel flow cold plate 400 of FIGS. 4B, 5A, and 5B, after the fluid is heated or warmed in accordance with an embodiment.

FIG. 6 is a block diagram which illustrates an overall system that includes an optical cage and a liquid cooling system in accordance with an embodiment.

FIG. 7 is a hardware block diagram of a networking/computing device/apparatus/appliance/endpoint that may perform functions associated with any combination of operations in connection with the techniques described with respect to FIGS. 1-3, 4A, 4B, 5A, 5B, 5C, and 6.

### DETAILED DESCRIPTION

### Overview

Techniques are presented herein that enable components of an optical network that are contained in an optical cage to be cooled. A liquid cooling system arranged to cool components such as optical network components includes a cold plate assembly with multiple ports that supports fluid flow in parallel through the multiple ports such that cooling may be provided while reducing pressure drops.

According to one aspect, an apparatus includes an inlet, the inlet configured to obtain a fluid, an outlet; a manifold, and at least a first port assembly. The manifold includes a first flow chamber and a second flow chamber. The first flow chamber is configured to obtain the fluid from the inlet, and the second flow chamber configured to provide the fluid to the outlet. The first port assembly includes a plurality of first port assembly tunnels, the plurality of first port assembly tunnels including a lower first port assembly tunnel, an upper first port assembly tunnel, and a u-turn first port assembly tunnel, wherein the fluid is provided from the first flow chamber to the lower first port assembly tunnel, the fluid further being provided from the lower first port assembly tunnel to the u-turn first port assembly tunnel, the fluid still further being provided from the u-turn first port assembly tunnel to the upper first port assembly tunnel. The fluid is provided from the upper first port assembly tunnel to the second flow chamber.

In accordance with another embodiment, an apparatus includes at least a first component and a cold plate assembly configured to cool the first component. The cold plate assembly includes an inlet, an outlet, a manifold, and a plurality of port assemblies. The inlet is configured to obtain a fluid, and the manifold includes a first flow chamber and a second flow chamber. The first flow chamber is configured to obtain the fluid from the inlet, and the second flow chamber is configured to provide the fluid to the outlet. Each of the plurality of port assemblies is in fluid communication with the manifold. The plurality of port assemblies is configured to obtain the fluid from the first chamber in parallel and to heat the fluid within the plurality of port assemblies, and the plurality of port assemblies is further configured to provide the fluid to the second flow chamber after heating the fluid.

According to still another embodiment, a method includes obtaining a fluid in a first flow chamber of a manifold, the manifold being included in a cold plate assembly, the manifold further including a second flow chamber, wherein the cold plate assembly further includes at least a first port assembly and a second port assembly; providing the fluid from the first flow chamber to the first port assembly. The method also includes providing the fluid from the first flow chamber to the second port assembly, wherein providing the fluid from the first flow chamber to the second port assembly occurs in parallel to providing the fluid from the first flow chamber to the first port assembly, and heating the fluid in the first port assembly and in the second port assembly. The fluid is provided from the first port assembly to the second flow chamber after heating the fluid, and the fluid is provided from the second port assembly to the second flow chamber, wherein providing the fluid from the second port assembly to the second flow chamber occurs in parallel to providing the fluid from the first port assembly to the second flow chamber.

### EXAMPLE EMBODIMENTS

The ability to provide cooling to components in a network, e.g., optical components in an optical network, enables the components to perform to expectations. Cooling may be provided to components in a network through the use of liquid cooling systems which utilize cold plates. Heat loads from components may be absorbed by fluid or liquid that flows through cold plates. While the use of cold plates is effective, cold plates are often inefficient, and occupy a significant amount of space. As will be appreciated by those skilled in the art, fluid flow through cold plates may be characterized by pressure drops, and cold plates may have a relatively large footprint.

A cold plate assembly that enables fluid flow to be achieved in parallel within multiple ports of the cold plate assembly enables cooling to be provided to network components while reducing pressure with a relatively compact footprint. The one or more ports of such a parallel flow compact cold plate assembly may be configured to enable fluid to flow through flow tunnels that are effectively stacked within the ports to enable the flow of fluid to occur substantially in parallel. When flow channels associated with the ports provide substantially the same ability to provide cooling and, hence, substantially the same cooling capacity, the predictability of the temperature across the ports may generally be improved. In addition, multiple flow channels in a cold plate assembly that provide substantially the same ability to provide cooling may also be characterized by a relatively low pressure drop within the cold plate assembly.

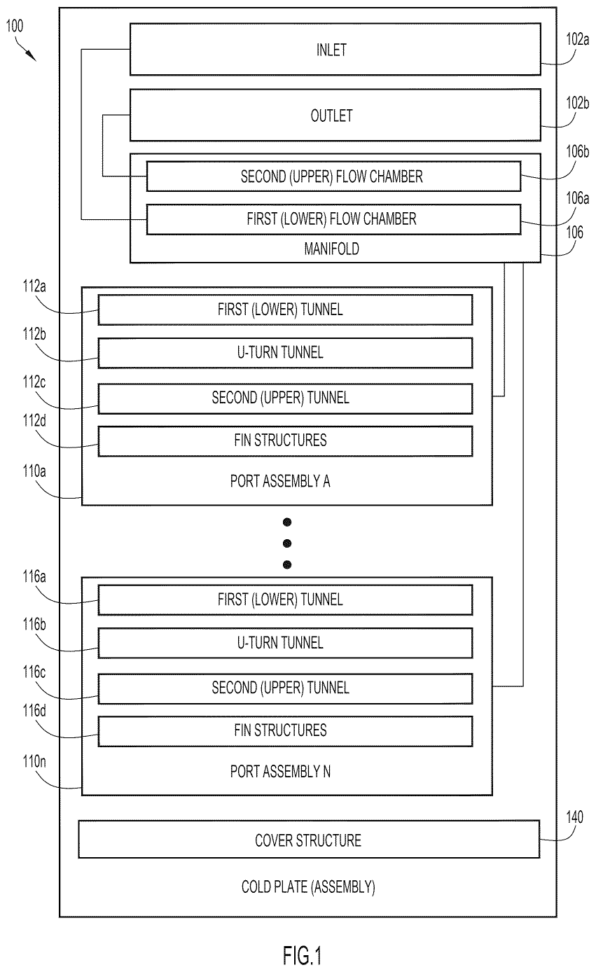

Referring initially to FIG. 1, a cold plate that enables fluid flow to be achieved in parallel with respect to port assemblies will be described in accordance with an embodiment. A cold plate 100, which may be a parallel flow compact cold plate or a parallel flow compact cold plate assembly, includes an inlet 102a, an outlet 102b, a manifold 106, port assemblies 110a-n, and a cover structure 140.

Inlet 102a is configured to obtain a fluid, as for example a cold fluid, from a fluid source (not shown), and to provide the fluid to a first flow chamber 106a of manifold 106. First flow chamber 106a, which may be a lower flow chamber of manifold 106, is configured to provide the fluid to port assemblies 110a-n substantially in parallel such that the fluid absorbs heat and is, therefore, heated or warmed within port assemblies 110a-n. The heated or warm fluid flows from port assemblies 110a-n substantially in parallel into a second flow chamber 106b of manifold 106. In general, second flow chamber 106b, which may be an upper flow chamber 106b of manifold 106, is separated from first flow chamber 106a such that the fluid does not flow substantially directly between first flow chamber 106a and second flow chamber 106b.

Outlet 102b is configured to obtain the fluid, as for example a heated or warm fluid, from second flow chamber 106b. Outlet 102b may generally be coupled to a fluid source (not shown) or reservoir that enables the heated or warm fluid to be cooled, e.g., cooled before being provided to inlet 102a.

The number of port assemblies 110a-n, which may be optic port assemblies, included in cold plate 100 may vary based on factors including, but not limited to including, the size of an area to be cooled and/or the size of each port assembly 110a-n. Port assemblies 110a-n may each include substantially the same components. A first port assembly 110a, or port assembly “A”, includes a first tunnel 112a, a u-turn tunnel 112b, a second tunnel 112c, and fin structures 112d. A port assembly 110n, or port assembly “N”, includes a first tunnel 116a, a u-turn tunnel 116b, a second tunnel 116c, and fin structures 116d.

First tunnel 112a and first tunnel 116a may be lower tunnels, or tunnels located on a lower or bottom side of port assembly 110a and port assembly 110n, respectively. In one embodiment, the lower or bottom side of port assembly 110a and port assembly 110n may be arranged in proximity to, or adjacent to, an optical cage to absorb heat emanating from the optical cage. First tunnel 112a and first tunnel 116a are in fluid communication with manifold 106. In one embodiment, fluid that flows through first flow chamber 106a may flow substantially in parallel into first tunnel 112a and first tunnel 116a.

First tunnel 112a is effectively connected to second tunnel 112c, which may be an upper tunnel, or a tunnel located on an upper or top side of port assembly 110a, through a u-turn tunnel 112b. Similarly, first tunnel 116a is effectively connected to second tunnel 116c, which may be an upper tunnel, or a tunnel located on an upper or top side of port assembly 110n, through a u-turn tunnel 116b. Second tunnel 112c and second tunnel 116c are in fluid communication with manifold 106 such that fluid flows out of second tunnel 112c and second tunnel 116c substantially in parallel into second flow chamber 106b.

Fin structures 112d and fin structures 116d are arranged to facilitate the transfer of heat from surfaces of cold plate 100 to fluid that flows through port assembly 110a and port assembly 110n, respectively. A fluid may effectively flow around fin structures 112d and fin structures 116d such that heat from components external to cold plate 100, e.g., optical components contained in an optical cage, that is provided to fin structures 112d and fin structures 116d may be transferred to, or otherwise absorbed by, the fluid.

Cover structure 140 is generally arranged to at least partially encase cold plate 100. For example, cover structure 140 may be formed to contain manifold 106 and port assemblies 110a-n, while effectively enabling inlet 102a and outlet 102b to be substantially externally exposed to enable fluid to flow from an external source into inlet 102a and to enable the fluid to flow out of outlet 102b to an external reservoir. In one embodiment, cover structure 140 may include a top cover, a bottom cover, and a middle structure formed from a metallic material that has a relatively high thermal conductivity. By way of example, suitable materials may include, but are not limited to including, copper, aluminum, brass, and steel. The top cover, bottom cover, and middle structure may be brazed together. It should be appreciated, however, that cover structure 140 is not limited to including a top cover, a bottom cover, and a middle structure.

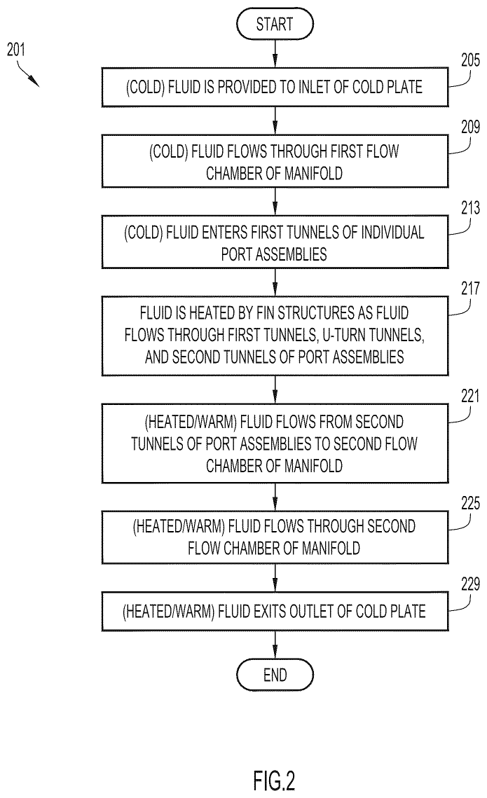

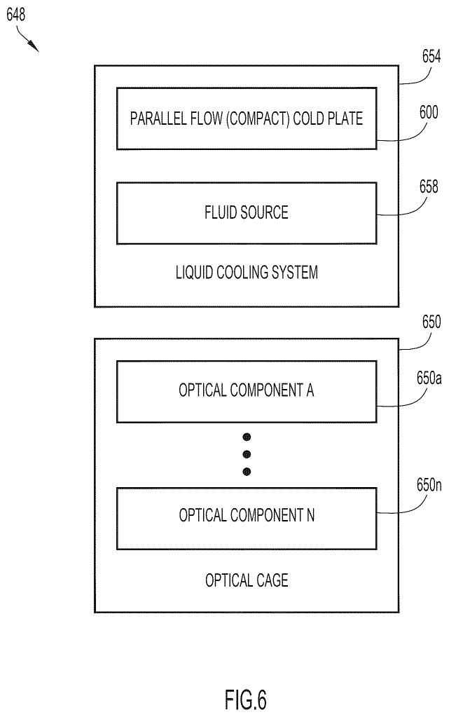

With reference to FIG. 2, a process of providing cooling using a parallel flow cold plate such as parallel flow cold plate 100 of FIG. 1 will be described in accordance with an embodiment. A method 201 of using a parallel flow cold plate begins at a step 205 in which a fluid, as for example a cold fluid, is provided to an inlet of a cold plate. The fluid may generally be any suitable fluid or liquid that may absorb heat. For example, the fluid may be, but is not limited to being, a refrigerant, deionized water, purified water, and/or a mixture of glycol and water. The fluid may be provided from a fluid source such as a reservoir that is part of a liquid cooling system that includes the parallel flow cold plate. A liquid cooling system will be discussed below with respect to FIG. 6.

Once a fluid is provided to the inlet of a cold plate, the fluid flows through a first flow chamber of a manifold in a step 209. For example, fluid flows through first flow chamber 106a of manifold 106 of FIG. 1. In one embodiment, the first flow chamber may be a lower flow chamber or a flow chamber located on a bottom side of a cold plate, or a side of a cold plate that is in close proximity to or in contact with an optical cage.

In a step 213, the fluid flows from the first flow chamber of the manifold into first tunnels of individual port assemblies of the cold plate. For example, fluid flows into first tunnel 112a of port assembly “A” 110a and first tunnel 116a of port assembly “N” 110n of FIG. 1. The fluid flows into the first tunnels, which may be lower tunnels with respect to the port assemblies, substantially in parallel. That is, the fluid may flow into each of the first tunnels substantially directly from the first flow channel.

After the fluid enters the first tunnels of the individual port assemblies, the fluid is heated by fin structures as the fluid flows through the first tunnels, u-turn tunnels, and second tunnels of the individual port assemblies in a step 217. As the fluid flows through the channels that include the first tunnels, the u-turn tunnels, and the second tunnels of the individual port assemblies substantially in parallel, the fluid is heated or warmed such that the temperature of the fluid in the individual port assemblies may be approximately the same. In addition, the pressure drop associated with the fluid as the fluid flows through the channels of the individual port assemblies may be approximately the same, relatively low amount for each port assembly.

In a step 221, the heated or warm fluid flows from the second tunnels of the port assemblies to a second flow chamber of the manifold. The heated or warm fluid generally flows in parallel from each of the second tunnels into the second flow chamber of the manifold.

The heated or warm fluid may flow out of the second channels or tunnels of the individual port assemblies and through a second flow chamber of a manifold in a step 225. For example, fluid may flow out of second tunnel 112c and second tunnel 116c and into second flow chamber 106b of cold plate 100 of FIG. 1. The flow of fluid out of the second channels may occur in parallel, or such that the flow of fluid to into a second flow channel of a manifold is substantially directly from each of the second channels.

The heated or warm fluid may flow through the second flow chamber of the manifold, and exit out of the cold plate through an outlet in a step 229. For example, the fluid may flow through second flow chamber 106b to an outlet 102b of cold plate 100 of FIG. 1. The heated or warm fluid may flow out of the outlet to a receptacle, e.g., a reservoir, to enable the fluid to be substantially cooled. It should be appreciated that the fluid may be cooled such that the cold fluid may be provided to the inlet of the cold plate. The method of using a parallel flow cold plate is completed once the fluid exits the outlet of the parallel flow cold plate.

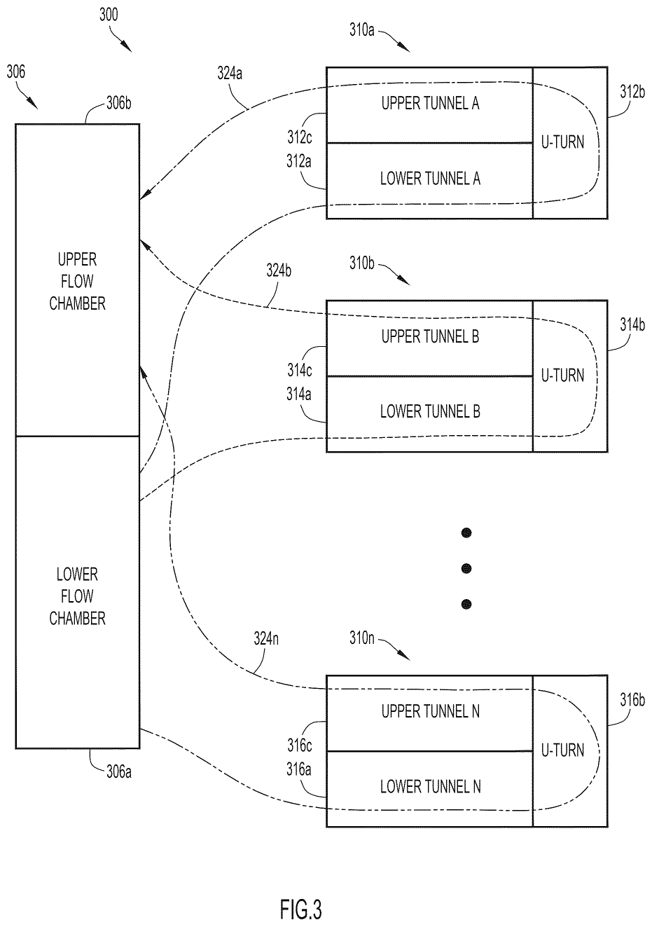

When fluid is provided to port assemblies of a cold plate substantially in parallel, or such that the fluid does not flow through one port assembly to another port assembly, the amount of a pressure drop in the fluid as it flows through the cold plate may be reduced, and the temperature of the fluid within each port assembly may be consistent or approximately the same. The flow channels, or flow paths, of the fluid through a cold plate will be described with respect to FIG. 3. FIG. 3 is a diagrammatic representation of an overall fluid flow within a parallel flow cold plate in accordance with an embodiment. A cold plate 300 includes a manifold 306 and port assemblies 310a-n. Manifold 306 includes a lower flow chamber 306a and an upper flow chamber 306b, e.g., lower flow chamber 306a may be positioned substantially beneath upper flow chamber 306b. Lower flow chamber 306a is arranged to obtain cooled or cold fluid and to provide the cooled or cold fluid to port assemblies 310a-n, while upper flow chamber 306b is arranged to obtain heated or warm fluid from port assemblies 310a-n. Widths of the channels in the upper flow chamber and of the channels in the lower flow chamber may be substantially the same, and thus evenly split.

Within cold plate 300, port assembly fluid flow paths 324a-n or port assembly fluid flow channels that facilitate absorbing heat generated by an element being cooled using cold plate 300, e.g., an optical cage. Fluid flow paths 324a-n are parallel flow paths in that effectively none of the fluid flow paths 324a-n passes through more than one port assembly 310a-n. For example, parallel fluid flow paths 324a-n may formed form substantially independent streams in which each fluid flow path 324a-n remains substantially separate from adjacent fluid flow paths 324a-n such that the fluid that flows through fluid flow paths 324a-n effectively mixes substantially only within lower flow chamber 306a and upper flow chamber 306b.

First fluid flow path 324a or first fluid flow channel provides fluid from lower flow chamber 306a to a first lower tunnel 312a of first port assembly 310a. Within first port assembly 310a, first fluid flow path 324a flows through first lower tunnel 312a to first u-turn tunnel 312b to first upper tunnel 312c. Fluid that flows through first port assembly 310a along first fluid flow path 324a is heated or warmed. First fluid flow path 324a is arranged to enable the heated or warm fluid to flow out of first upper tunnel 312c and into upper flow chamber 306b.

Second fluid flow path 324b or second fluid flow channel provides fluid from lower flow chamber 306a to a second lower tunnel 314a of second port assembly 310b. Within second port assembly 310b, second fluid flow path 324b flows through second lower tunnel 314a to second u-turn tunnel 314b to second upper tunnel 314c. Fluid that flows through second port assembly 310b along second fluid flow path 324b is heated or warmed. Second fluid flow path 324b is arranged to enable the heated or warm fluid to flow out of second upper tunnel 314c and into upper flow chamber 306b.

Nth fluid flow path 324n or Nth fluid flow channel provides fluid from lower flow chamber 306a to an Nth lower tunnel 316a of Nth port assembly 310n. Within Nth port assembly 310n, Nth fluid flow path 324n flows through Nth lower tunnel 316a to Nth u-turn tunnel 316b to Nth upper tunnel 316c. Fluid that flows through Nth port assembly 310n along Nth fluid flow path 324n is heated or warmed. Nth fluid flow path 324n is arranged to enable the heated or warm fluid to flow out of Nth upper tunnel 316c and into upper flow chamber 306b.

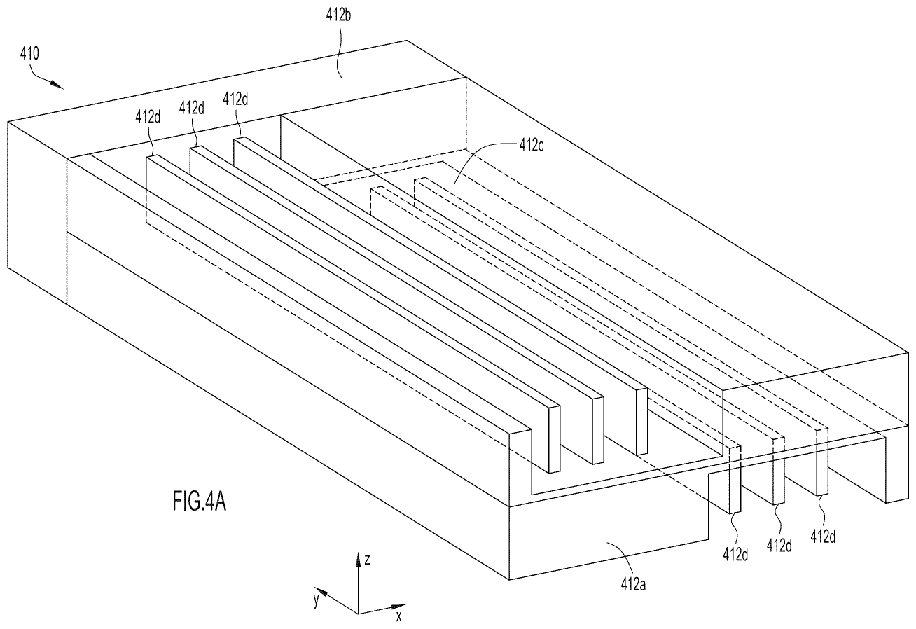

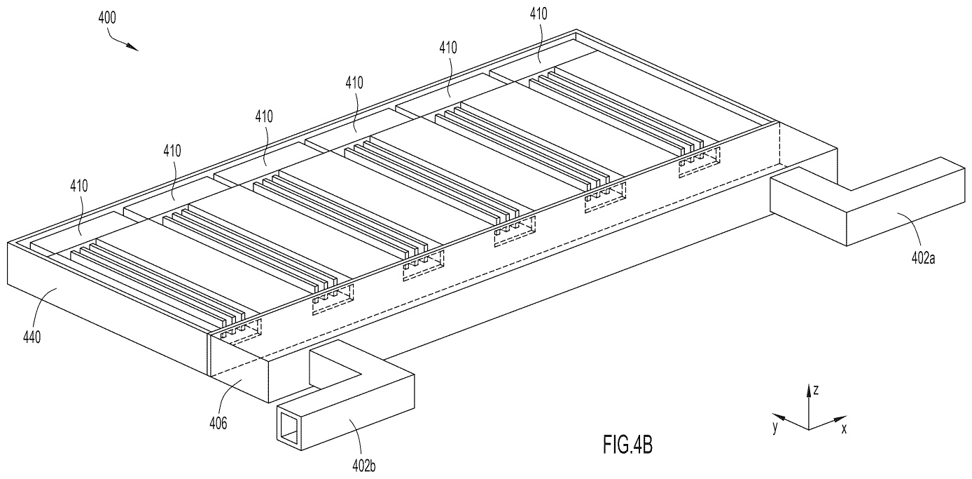

FIG. 4A is a diagrammatic representation of a port assembly that is suitable for use in a parallel flow cold plate in accordance with an embodiment. A port assembly 410 includes a first or lower tunnel 412a, a u-turn tunnel 412b, and a second or upper tunnel 412c. A plurality of fins or fin structures 412d are provided in port assembly 410 to facilitate the transfer of heat to a fluid that flows through tunnels 412a-c.

As fluid flows into first tunnel 412a along a y-axis, fluid begins to absorb heat and continues to absorb heat as fluid flows through u-turn tunnel 412b and through second tunnel 412c. Heated or warm fluid flows out of second tunnel 412c along the y-axis in a substantially opposite direction from the direction in which cooled or cold fluid flows into first tunnel 412a. As shown, first tunnel 412a is positioned below second tunnel 412c relative to a z-axis. In other words, first tunnel 412a is a lower tunnel and second tunnel 412c is an upper tunnel relative to the z-axis.

Multiple port assemblies 410 are generally included in a cold plate. FIG. 4B is a diagrammatic representation of a parallel flow cold plate that includes a plurality of port assemblies 410 in accordance with an embodiment. A parallel flow cold plate 400 includes a plurality of port assemblies 410, a manifold 406, an inlet 402a, and an outlet 402b. Cold plate 400 also includes a cover structure 440 that is arranged to substantially encase port assemblies 410 and manifold 406. Cover structure 440 is shown without a top cover for purposes of illustration.

While six port assemblies 410 are shown as being included in cold plate 400, it should be appreciated that the number of port assemblies 410 included in cold plate may vary widely. Port assemblies 410 may be configured to substantially abut against one another.

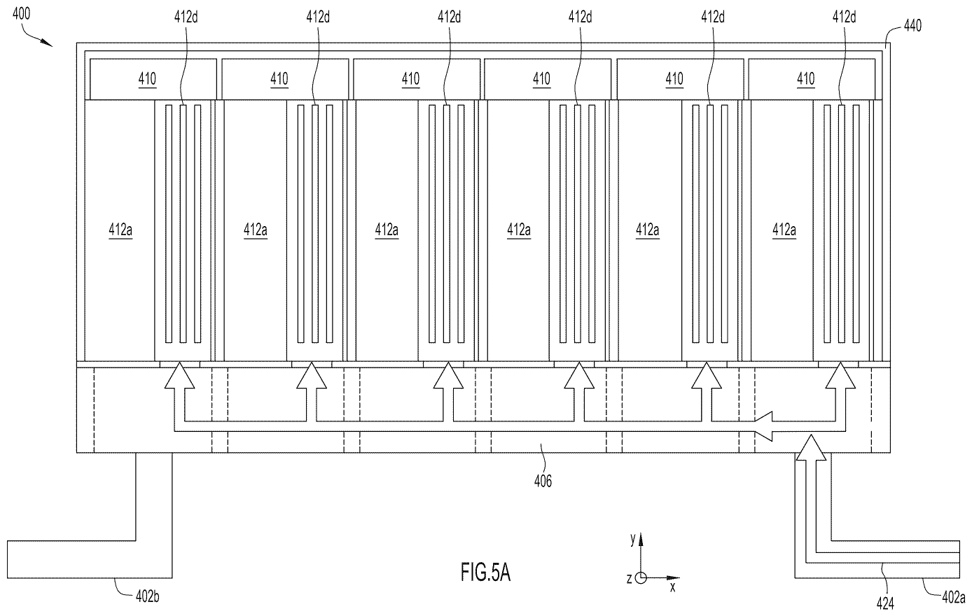

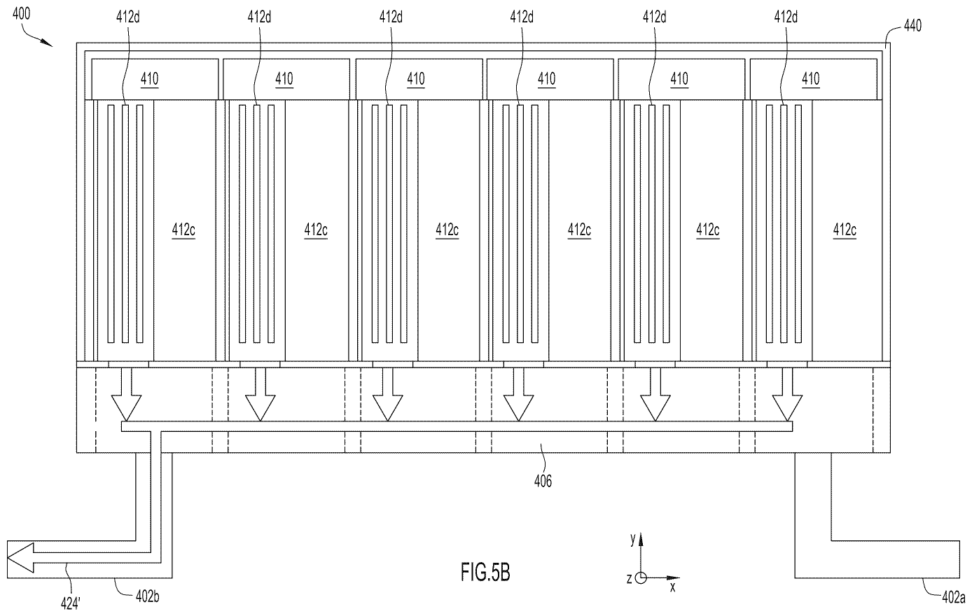

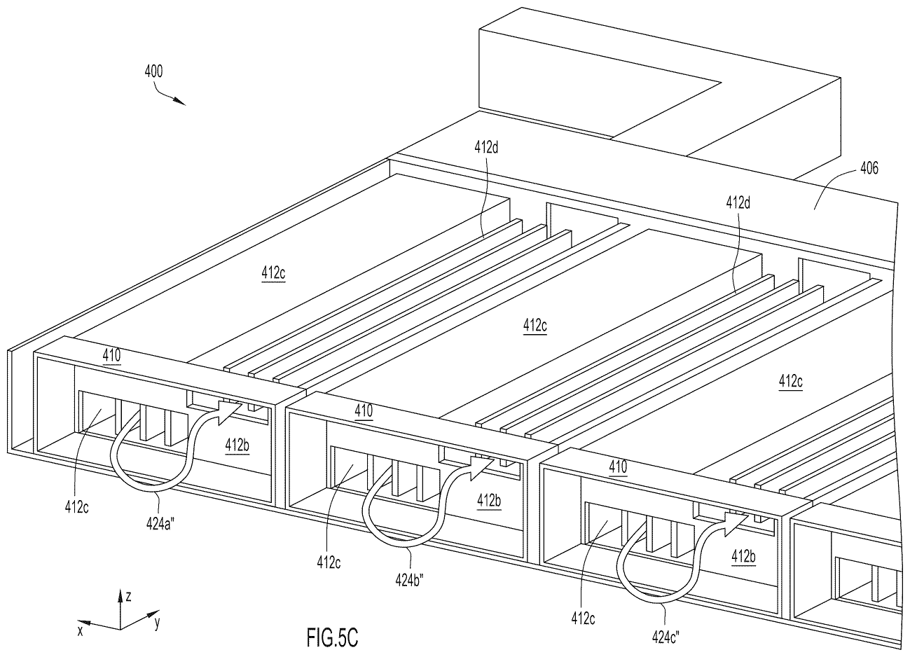

The flow of fluid through a cold plate 400 will be discussed with reference to FIGS. 5A-C. FIG. 5A is a diagrammatic representation of a flow of fluid through cold plate 400 prior to the fluid being heated or warmed in accordance with an embodiment. A fluid flow 424 through cold plate 400 begins at inlet 402a, and proceeds to manifold 406, e.g., into a first flow chamber of manifold 406.

Fluid flow 424 through manifold 406 is such that fluid enters into first or lower tunnels 412a of port assemblies 410. As discussed above with respect to FIG. 3, each port assembly 410 has a port assembly fluid flow that is in parallel to the port assembly fluid flow of other port assemblies 410. Fluid flow 424 is provided to each individual port assembly fluid flow in parallel.

Fluid flow 424 becomes heated or warmed within port assemblies 410, and flows out of port assemblies 410 in a substantially warmed state. Warmed fluid flow 424′, as shown in FIG. 5B, flows out of port assemblies 410 and into manifold 406, e.g., into a second flow chamber of manifold 406. Warmed fluid flow 424′ may be substantially formed from warmed port assembly fluid flows that flows in parallel through port assemblies 410. From manifold 406, warmed fluid flow 424′ flows out of cold plate 400 through outlet 402b.

With reference to FIG. 5C, the flow of fluid through u-turn tunnels 412b will be described in accordance with an embodiment. FIG. 5C is a diagrammatic cut-away representation of cold plate 400 in accordance with an embodiment. U-turn tunnels 412b are configured to enable fluid that flows through lower tunnels 412a to flow into upper tunnels 412c. As shown, each port assembly 410 has a separate fluid flow 424a″-c″ through u-turn tunnels 412b. Fluid flows 424a″-c″ include a first fluid flow 424a″, a second fluid flow 424b″, and a third fluid flow 424c″.

As previously mentioned, a parallel flow cold plate may be used to provide cooling to an optical cage. For example, a parallel flow cold plate may be positioned such that lower tunnels of port assemblies included in the parallel flow cold plate are positioned substantially over, and in proximity to, an optical cage. FIG. 6 is a block diagram which illustrates an overall system that includes an optical cage and a liquid cooling system in accordance with an embodiment. An overall system 648 includes an optical cage 650 and a liquid cooling system 654 that is arranged to cool optical cage 650, i.e., to remove heat that emanates from or is otherwise generated by optical cage 650.

Optical cage 650 includes optical components 650a-n. Although optical component 650a and optical component 650n are shown, it should be appreciated that the number of optical components 650a-n included in optical cage 650 may vary widely. In general, optical cage 650 may be, but is not limited to being, a 1×N or a 2×N optical cage.

Liquid cooling system 654 includes a parallel flow cold plate 600 and a fluid source 658. Parallel flow cold plate 600 may include the elements included in parallel flow cold plate 100 of FIG. 1. Parallel flow cold plate 600 is generally positioned over, and in proximity to, optical cage 650 such that fluid carried through parallel flow cold plate 600 may absorb heat emanating from optical cage 650 to effectively remove heat from optical cage 650. Fluid source 658 may be a reservoir from which fluid that flows into parallel flow cold plate 600 may be obtained.

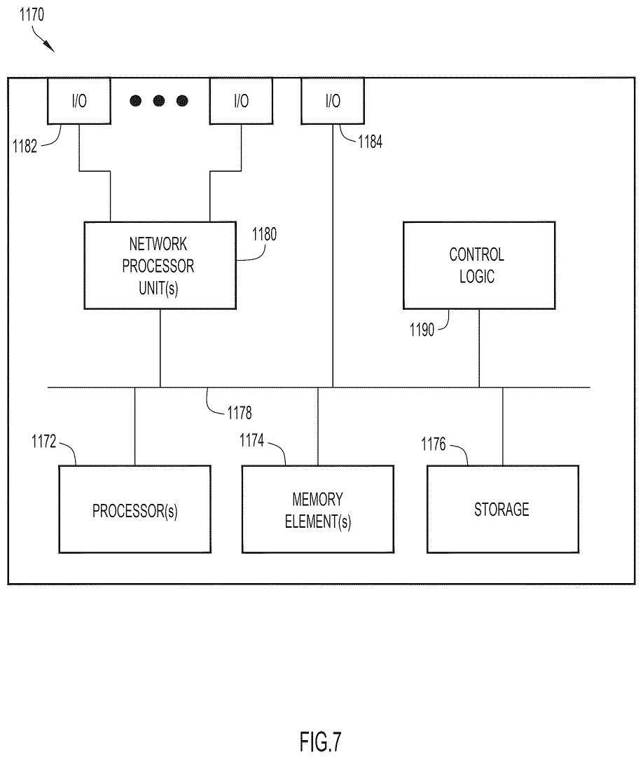

FIG. 7 is a hardware block diagram of a networking/computing device/apparatus/appliance/endpoint that may perform functions associated with any combination of operations in connection with the techniques described with respect to FIGS. 1-3, 4A, 4B, 5A, 5B, 5C, and 6, e.g., the networking/computing device/apparatus/appliance/endpoint may be embodied in or include an optical cage that is cooled using a parallel flow cold plate using the techniques described above. It should be appreciated that FIG. 7 provides only an illustration of one example embodiment and does not imply any limitations with regard to the environments in which different example embodiments may be implemented. Many modifications to the depicted environment may be made.

In at least one embodiment, the computing device 1170 may be any apparatus that may include one or more processor(s) 1172, one or more memory element(s) 1174, storage 1176, a bus 1178, one or more network processor unit(s) 1180 interconnected with one or more network input/output (I/O) interface(s) 1182, one or more I/O interface(s) 1184, and control logic 1190. In various embodiments, instructions associated with logic for computing device 1170 may overlap in any manner and are not limited to the specific allocation of instructions and/or operations described herein.

In at least one embodiment, processor(s) 1172 is/are at least one hardware processor configured to execute various tasks, operations and/or functions for device 1170 as described herein according to software and/or instructions configured for device 1170. Processor(s) 1172 (e.g., a hardware processor) may execute any type of instructions associated with data to achieve the operations detailed herein. In one example, processor(s) 1172 may transform an element or an article (e.g., data, information) from one state or thing to another state or thing. Any of potential processing elements, microprocessors, digital signal processor, baseband signal processor, modem, PHY, controllers, systems, managers, logic, and/or machines described herein may be construed as being encompassed within the broad term ‘processor’.

In at least one embodiment, one or more memory element(s) 1174 and/or storage 1176 is/are configured to store data, information, software, and/or instructions associated with device 1170, and/or logic configured for memory element(s) 1174 and/or storage 1176. For example, any logic described herein (e.g., control logic 1190) may, in various embodiments, be stored for device 1170 using any combination of memory element(s) 1174 and/or storage 1176. Note that in some embodiments, storage 1176 may be consolidated with one or more memory elements 1174 (or vice versa), or may overlap/exist in any other suitable manner. In one or more example embodiments, process data is also stored in the one or more memory elements 1174 for later evaluation and/or process optimization.

In at least one embodiment, bus 1178 may be configured as an interface that enables one or more elements of device 1170 to communicate in order to exchange information and/or data. Bus 1178 may be implemented with any architecture designed for passing control, data and/or information between processors, memory elements/storage, peripheral devices, and/or any other hardware and/or software components that may be configured for device 1170. In at least one embodiment, bus 1178 may be implemented as a fast kernel-hosted interconnect, potentially using shared memory between processes (e.g., logic), which may enable efficient communication paths between the processes.

In various embodiments, network processor unit(s) 1180 may enable communication between computing device 1170 and other systems, entities, etc., via network I/O interface(s) 1182 (wired and/or wireless) to facilitate operations discussed for various embodiments described herein. In various embodiments, network processor unit(s) 1180 may be configured as a combination of hardware and/or software, such as one or more Ethernet driver(s) and/or controller(s) or interface cards, Fibre Channel (e.g., optical) driver(s) and/or controller(s), wireless receivers/transmitters/transceivers, baseband processor(s)/modem(s), and/or other similar network interface driver(s) and/or controller(s) now known or hereafter developed to enable communications between computing device 1170 and other systems, entities, etc. to facilitate operations for various embodiments described herein. In various embodiments, network I/O interface(s) 1182 may be configured as one or more Ethernet port(s), Fibre Channel ports, any other I/O port(s), and/or antenna(s)/antenna array(s) now known or hereafter developed. Thus, the network processor unit(s) 1180 and/or network I/O interface(s) 1182 may include suitable interfaces for receiving, transmitting, and/or otherwise communicating data and/or information in a network environment.

I/O interface(s) 1184 allow for input and output of data and/or information with other entities that may be connected to device 1170. For example, I/O interface(s) 1184 may provide a connection to external devices such as a keyboard, keypad, a touch screen, and/or any other suitable input device now known or hereafter developed. In some instances, external devices may also include portable computer readable (non-transitory) storage media such as database systems, thumb drives, portable optical or magnetic disks, and memory cards.

In various embodiments, control logic 1190 may include instructions that, when executed, cause processor(s) 1172 to perform operations, which may include, but not be limited to, providing overall control operations of computing device; interacting with other entities, systems, etc. described herein; maintaining and/or interacting with stored data, information, parameters, etc. (e.g., memory element(s), storage, data structures, databases, tables, etc.); combinations thereof; and/or the like to facilitate various operations for embodiments described herein.

The programs described herein (e.g., control logic 1190) may be identified based upon the application(s) for which they are implemented in a specific embodiment. However, it should be appreciated that any particular program nomenclature herein is used merely for convenience, and thus the embodiments herein should not be limited to use(s) solely described in any specific application(s) identified and/or implied by such nomenclature.

In the event the device 1170 is an endpoint (such as telephone, mobile phone, desk phone, conference endpoint, etc.), then the device 1170 may further include a sound processor, a speaker that plays out audio, and a microphone that detects audio. A sound processor may be a sound accelerator card or other similar audio processor that may be based on one or more ASICs and associated digital-to-analog and analog-to-digital circuitry to convert signals between the analog domain and digital domain. In some forms, the sound processor may include one or more digital signal processors (DSPs) and be configured to perform some or all of the operations of the techniques presented herein. The device 1170 may further include a video camera.

Although only a few embodiments have been described in this disclosure, it should be understood that the disclosure may be embodied in many other specific forms without departing from the spirit or the scope of the present disclosure. By way of example, the configuration of port assemblies which obtain cold fluid in parallel from a first flow chamber and provide heated or warm fluid in parallel to a second flow chamber may vary.

In some aspects, the techniques described herein relate to an apparatus including: an inlet, the inlet configured to obtain a fluid; an outlet; a manifold, the manifold including a first flow chamber and a second flow chamber, the first flow chamber configured to obtain the fluid from the inlet, the second flow chamber configured to provide the fluid to the outlet; and at least a first port assembly, the at least first port assembly including a plurality of first port assembly tunnels, the plurality of first port assembly tunnels including a lower first port assembly tunnel, an upper first port assembly tunnel, and a u-turn first port assembly tunnel, wherein the fluid is provided from the first flow chamber to the lower first port assembly tunnel, the fluid further being provided from the lower first port assembly tunnel to the u-turn first port assembly tunnel, the fluid still further being provided from the u-turn first port assembly tunnel to the upper first port assembly tunnel, and wherein the fluid is provided from the upper first port assembly tunnel to the second flow chamber.

In some aspects, the techniques described herein relate to an apparatus wherein the fluid is heated in the at least first port assembly, and wherein the fluid provided from the upper first port assembly tunnel to the second flow chamber is a heated fluid.

In some aspects, the techniques described herein relate to an apparatus wherein the fluid obtained by the first flow chamber is cooled fluid.

In some aspects, the techniques described herein relate to an apparatus further including: a second port assembly including a plurality of second port assembly tunnels, the plurality of second port assembly tunnels including a lower second port assembly tunnel, an upper second port assembly tunnel, and a u-turn second port assembly tunnel, wherein the fluid is provided from the first flow chamber to the lower second port assembly tunnel, the fluid further being provided from the lower second port assembly tunnel to the u-turn second port assembly tunnel, the fluid still further being provided from the u-turn second port assembly tunnel to the upper second port assembly tunnel, and wherein the fluid is provided from the upper second port assembly tunnel to the second flow chamber.

In some aspects, the techniques described herein relate to an apparatus wherein the first flow chamber is configured to provide the fluid to the lower first port assembly tunnel and to the lower second port assembly tunnel in parallel.

In some aspects, the techniques described herein relate to an apparatus wherein the fluid is provided from the upper first port assembly tunnel to the second flow chamber and from the upper second port assembly tunnel to the second flow chamber in parallel.

In some aspects, the techniques described herein relate to an apparatus wherein the first port assembly includes at least a first fin structure arranged to heat the fluid and the second port assembly includes at least a second fin structure arranged to heat the fluid.

In some aspects, the techniques described herein relate to an apparatus including: at least a first component; and a cold plate assembly configured to cool the first component, the cold plate assembly including: an inlet, the inlet configured to obtain a fluid; an outlet; a manifold, the manifold including a first flow chamber and a second flow chamber, the first flow chamber configured to obtain the fluid from the inlet, the second flow chamber configured to provide the fluid to the outlet; and a plurality of port assemblies, the plurality of port assemblies each being in fluid communication with the manifold, the plurality of port assemblies being configured to obtain the fluid from the first chamber in parallel and to heat the fluid within the plurality of port assemblies, the plurality of port assemblies further being configured to provide the fluid to the second flow chamber after heating the fluid.

In some aspects, the techniques described herein relate to an apparatus wherein the plurality of port assemblies includes a plurality of fin structures, the plurality of fin structures being configured to absorb a heat from the first component and to heat the fluid.

In some aspects, the techniques described herein relate to an apparatus wherein the plurality of port assemblies includes: a first port assembly including a lower first port assembly tunnel, an upper first port assembly tunnel, and a u-turn first port assembly tunnel, wherein the fluid is provided from the first flow chamber to the lower first port assembly tunnel, the fluid further being provided from the lower first port assembly tunnel to the u-turn first port assembly tunnel, the fluid still further being provided from the u-turn first port assembly tunnel to the upper first port assembly tunnel, and wherein the fluid is provided from the upper first port assembly tunnel to the second flow chamber; and a second port assembly including a lower second port assembly tunnel, an upper second port assembly tunnel, and a u-turn second port assembly tunnel, wherein the fluid is provided from the first flow chamber to the lower second port assembly tunnel, the fluid further being provided from the lower second port assembly tunnel to the u-turn second port assembly tunnel, the fluid still further being provided from the u-turn second port assembly tunnel to the upper second port assembly tunnel, and wherein the fluid is provided from the upper second port assembly tunnel to the second flow chamber.

In some aspects, the techniques described herein relate to an apparatus wherein the first flow chamber is configured to provide the fluid to the lower first port assembly tunnel and to the lower second port assembly tunnel in parallel.

In some aspects, the techniques described herein relate to an apparatus wherein the fluid is provided from the upper first port assembly tunnel to the second flow chamber and from the upper second port assembly tunnel to the second flow chamber in parallel.

In some aspects, the techniques described herein relate to an apparatus wherein the fluid is heated in the first port assembly and the second port assembly, and wherein the fluid provided from the upper first port assembly tunnel to the second flow chamber and from the upper second port assembly tunnel to the second flow chamber is heated fluid.

In some aspects, the techniques described herein relate to an apparatus wherein the fluid obtained by the first flow chamber is cooled fluid.

In some aspects, the techniques described herein relate to a method including: obtaining a fluid in a first flow chamber of a manifold, the manifold being included in a cold plate assembly, the manifold further including a second flow chamber, wherein the cold plate assembly further includes at least a first port assembly and a second port assembly; providing the fluid from the first flow chamber to the first port assembly; providing the fluid from the first flow chamber to the second port assembly, wherein providing the fluid from the first flow chamber to the second port assembly occurs in parallel to providing the fluid from the first flow chamber to the first port assembly; heating the fluid in the first port assembly and in the second port assembly; providing the fluid from the first port assembly to the second flow chamber after heating the fluid; and providing the fluid from the second port assembly to the second flow chamber, wherein providing the fluid from the second port assembly to the second flow chamber occurs in parallel to providing the fluid from the first port assembly to the second flow chamber.

In some aspects, the techniques described herein relate to a method wherein the cold plate assembly includes an inlet and an outlet, wherein obtaining the fluid in the first flow chamber include obtaining the fluid from the inlet, the method further including: providing the fluid from the second flow chamber to the outlet.

In some aspects, the techniques described herein relate to a method wherein the cold plate assembly is configured to cool a component that generates a heat, and wherein the first port assembly includes a first plurality of fin structures and the second port assembly includes a second plurality of fin structures, the first plurality of fin structures being configured to absorb the heat from the first component and to heat the fluid in the first port assembly, the second plurality of fin structures being configured to absorb the heat from the first component and to heat the fluid in the second port assembly.

In some aspects, the techniques described herein relate to a method wherein the first port assembly includes a lower first port assembly tunnel, an upper first port assembly tunnel, and a u-turn first port assembly tunnel, and providing the fluid from the first flow chamber to the first port assembly includes providing the fluid from the first flow chamber to the lower first port assembly tunnel, the method further including: providing the fluid from the lower first port assembly tunnel to the u-turn first port assembly tunnel; and providing the fluid from the u-turn first port assembly tunnel to the upper first port assembly tunnel, and wherein providing the fluid from the first port assembly to the second flow chamber after heating the fluid includes providing the fluid from the upper first port assembly tunnel to the second flow chamber.

In some aspects, the techniques described herein relate to a method wherein the second port assembly includes a lower second port assembly tunnel, an upper second port assembly tunnel, and a u-turn second port assembly tunnel, and providing the fluid from the first flow chamber to the second port assembly includes providing the fluid from the first flow chamber to the lower second port assembly tunnel, the method further including: providing the fluid from the lower second port assembly tunnel to the u-turn second port assembly tunnel; and providing the fluid from the u-turn second port assembly tunnel to the upper second port assembly tunnel, and wherein providing the fluid from the second port assembly to the second flow chamber includes providing the fluid from the upper second port assembly tunnel to the second flow chamber.

In some aspects, the techniques described herein relate to a method wherein the cold plate assembly is configured to cool an optical cage that includes at least one optical component, and wherein heating the fluid in the first port assembly and in the second port assembly includes heating the fluid using a heat generated by the at least one optical component.

In various embodiments, entities as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which may be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, the storage 1176 and/or memory elements(s) 1174 may store data, software, code, instructions (e.g., processor instructions), logic, parameters, combinations thereof, and/or the like used for operations described herein. This includes the storage 1176 and/or memory elements(s) 1174 being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

### Variations and Implementations

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi6®), IEEE 802.16 (e.g., Worldwide Interoperability for Microwave Access (WiMAX)), Radio-Frequency Identification (RFID), Near Field Communication (NFC), Bluetooth™, mm.wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

In various example implementations, any entity or apparatus for various embodiments described herein can encompass network elements (which can include virtualized network elements, functions, etc.) such as, for example, network appliances, forwarders, routers, servers, switches, gateways, bridges, loadbalancers, firewalls, processors, modules, radio receivers/transmitters, or any other suitable device, component, element, or object operable to exchange information that facilitates or otherwise helps to facilitate various operations in a network environment as described for various embodiments herein. Note that with the examples provided herein, interaction may be described in terms of one, two, three, or four entities. However, this has been done for purposes of clarity, simplicity and example only. The examples provided should not limit the scope or inhibit the broad teachings of systems, networks, etc. described herein as potentially applied to a myriad of other architectures.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein and in the claims, the term ‘packet’ may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/−5%, within +/−4%, within +/−3%, within +/−2%, within +/−1%, or even closer, of the given value.

Similarly, when a given feature is described as being “substantially parallel” to another feature, “generally perpendicular” to another feature, and so forth, this is intended to convey that the given feature is within +/−5%, within +/−4%, within +/−3%, within +/−2%, within +/−1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
an inlet, the inlet configured to obtain a fluid;
an outlet;
a manifold, the manifold including a first flow chamber and a second flow chamber, the first flow chamber configured to obtain the fluid from the inlet, the second flow chamber configured to provide the fluid to the outlet; and
at least a first port assembly, the at least first port assembly including a plurality of first port assembly tunnels, the plurality of first port assembly tunnels including a lower first port assembly tunnel, an upper first port assembly tunnel, and a u-turn first port assembly tunnel, wherein the fluid is provided from the first flow chamber to the lower first port assembly tunnel, the fluid further being provided from the lower first port assembly tunnel to the u-turn first port assembly tunnel, the fluid still further being provided from the u-turn first port assembly tunnel to the upper first port assembly tunnel, and wherein the fluid is provided from the upper first port assembly tunnel to the second flow chamber.

2. The apparatus of claim 1 wherein the fluid is heated in the at least first port assembly, and wherein the fluid provided from the upper first port assembly tunnel to the second flow chamber is a heated fluid.

3. The apparatus of claim 2 wherein the fluid obtained by the first flow chamber is cooled fluid.

4. The apparatus of claim 1 further including:
a second port assembly including a plurality of second port assembly tunnels, the plurality of second port assembly tunnels including a lower second port assembly tunnel, an upper second port assembly tunnel, and a u-turn second port assembly tunnel, wherein the fluid is provided from the first flow chamber to the lower second port assembly tunnel, the fluid further being provided from the lower second port assembly tunnel to the u-turn second port assembly tunnel, the fluid still further being provided from the u-turn second port assembly tunnel to the upper second port assembly tunnel, and wherein the fluid is provided from the upper second port assembly tunnel to the second flow chamber.

5. The apparatus of claim 4 wherein the first flow chamber is configured to provide the fluid to the lower first port assembly tunnel and to the lower second port assembly tunnel in parallel.

6. The apparatus of claim 5 wherein the fluid is provided from the upper first port assembly tunnel to the second flow chamber and from the upper second port assembly tunnel to the second flow chamber in parallel.

7. The apparatus of claim 4 wherein the first port assembly includes at least a first fin structure arranged to heat the fluid and the second port assembly includes at least a second fin structure arranged to heat the fluid.

8. An apparatus comprising:
at least a first component; and
a cold plate assembly configured to cool the first component, the cold plate assembly including:
an inlet, the inlet configured to obtain a fluid;
an outlet;
a manifold, the manifold including a first flow chamber and a second flow chamber, the first flow chamber configured to obtain the fluid from the inlet, the second flow chamber configured to provide the fluid to the outlet; and
a plurality of port assemblies, the plurality of port assemblies each being in fluid communication with the manifold, the plurality of port assemblies being configured to obtain the fluid from the first chamber in parallel and to heat the fluid within the plurality of port assemblies, the plurality of port assemblies further being configured to provide the fluid to the second flow chamber after heating the fluid.

9. The apparatus of claim 8 wherein the plurality of port assemblies includes a plurality of fin structures, the plurality of fin structures being configured to absorb a heat from the first component and to heat the fluid.

10. The apparatus of claim 8 wherein the plurality of port assemblies includes:
a first port assembly including a lower first port assembly tunnel, an upper first port assembly tunnel, and a u-turn first port assembly tunnel, wherein the fluid is provided from the first flow chamber to the lower first port assembly tunnel, the fluid further being provided from the lower first port assembly tunnel to the u-turn first port assembly tunnel, the fluid still further being provided from the u-turn first port assembly tunnel to the upper first port assembly tunnel, and wherein the fluid is provided from the upper first port assembly tunnel to the second flow chamber; and
a second port assembly including a lower second port assembly tunnel, an upper second port assembly tunnel, and a u-turn second port assembly tunnel, wherein the fluid is provided from the first flow chamber to the lower second port assembly tunnel, the fluid further being provided from the lower second port assembly tunnel to the u-turn second port assembly tunnel, the fluid still further being provided from the u-turn second port assembly tunnel to the upper second port assembly tunnel, and wherein the fluid is provided from the upper second port assembly tunnel to the second flow chamber.

11. The apparatus of claim 10 wherein the first flow chamber is configured to provide the fluid to the lower first port assembly tunnel and to the lower second port assembly tunnel in parallel.

12. The apparatus of claim 11 wherein the fluid is provided from the upper first port assembly tunnel to the second flow chamber and from the upper second port assembly tunnel to the second flow chamber in parallel.

13. The apparatus of claim 12 wherein the fluid is heated in the first port assembly and the second port assembly, and wherein the fluid provided from the upper first port assembly tunnel to the second flow chamber and from the upper second port assembly tunnel to the second flow chamber is heated fluid.

14. The apparatus of claim 13 wherein the fluid obtained by the first flow chamber is cooled fluid.

15. A method comprising:
obtaining a fluid in a first flow chamber of a manifold, the manifold being included in a cold plate assembly, the manifold further including a second flow chamber, wherein the cold plate assembly further includes at least a first port assembly and a second port assembly;
providing the fluid from the first flow chamber to the first port assembly;
providing the fluid from the first flow chamber to the second port assembly, wherein providing the fluid from the first flow chamber to the second port assembly occurs in parallel to providing the fluid from the first flow chamber to the first port assembly;
heating the fluid in the first port assembly and in the second port assembly;
providing the fluid from the first port assembly to the second flow chamber after heating the fluid; and
providing the fluid from the second port assembly to the second flow chamber, wherein providing the fluid from the second port assembly to the second flow chamber occurs in parallel to providing the fluid from the first port assembly to the second flow chamber.

16. The method of claim 15 wherein the cold plate assembly includes an inlet and an outlet, wherein obtaining the fluid in the first flow chamber include obtaining the fluid from the inlet, the method further including:
providing the fluid from the second flow chamber to the outlet.

17. The method of claim 15 wherein the cold plate assembly is configured to cool a component that generates a heat, and wherein the first port assembly includes a first plurality of fin structures and the second port assembly includes a second plurality of fin structures, the first plurality of fin structures being configured to absorb the heat from the first component and to heat the fluid in the first port assembly, the second plurality of fin structures being configured to absorb the heat from the first component and to heat the fluid in the second port assembly.

18. The method of claim 15 wherein the first port assembly includes a lower first port assembly tunnel, an upper first port assembly tunnel, and a u-turn first port assembly tunnel, and providing the fluid from the first flow chamber to the first port assembly includes providing the fluid from the first flow chamber to the lower first port assembly tunnel, the method further comprising:
providing the fluid from the lower first port assembly tunnel to the u-turn first port assembly tunnel; and
providing the fluid from the u-turn first port assembly tunnel to the upper first port assembly tunnel, and wherein providing the fluid from the first port assembly to the second flow chamber after heating the fluid includes providing the fluid from the upper first port assembly tunnel to the second flow chamber.

19. The method of claim 18 wherein the second port assembly includes a lower second port assembly tunnel, an upper second port assembly tunnel, and a u-turn second port assembly tunnel, and providing the fluid from the first flow chamber to the second port assembly includes providing the fluid from the first flow chamber to the lower second port assembly tunnel, the method further comprising:
providing the fluid from the lower second port assembly tunnel to the u-turn second port assembly tunnel; and
providing the fluid from the u-turn second port assembly tunnel to the upper second port assembly tunnel, and wherein providing the fluid from the second port assembly to the second flow chamber includes providing the fluid from the upper second port assembly tunnel to the second flow chamber.

20. The method of claim 15 wherein the cold plate assembly is configured to cool an optical cage that includes at least one optical component, and wherein heating the fluid in the first port assembly and in the second port assembly includes heating the fluid using a heat generated by the at least one optical component.
